(19) United States
(12) Patent Application Publication
(10) Pub. No.: US 2026/0271382 A1
(43) Pub. Date: Sep. 10, 2026

(54) SEMICONDUCTOR DEVICES

(71) Applicant: Samsung Electronics Co., Ltd., Suwon-si (KR)

(72) Inventors: Sanghyun LEE, Suwon-si (KR); Hyonwook RA, Suwon-si (KR); Jongchul PARK, Suwon-si (KR); Jieun HAN, Suwon-si (KR)

(73) Assignee: Samsung Electronics Co., Ltd., Suwon-si (KR)

(21) Appl. No.: 19/531,204

(22) Filed: Feb. 5, 2026

(30) Foreign Application Priority Data
Mar. 4, 2025 (KR) 10-2025-0027628

(51) Int. Cl. H10D 84/83; H10D 30/00; H10D 30/01; H10D 62/13; H10D 64/23; H10D 64/27; H10D 64/62; H10D 64/66; H10D 84/01; H10W 20/41; H10W 20/42

(52) U.S. Cl. CPC H10D 84/832; H10D 30/503; H10D 62/151; H10D 64/256; H10D 64/518; H10D 64/62; H10D 64/665; H10D 84/8312; H10W 20/422; H10W 20/435; H10D 30/019; H10D 84/0149

(57) ABSTRACT

A semiconductor device includes an active pattern extending on a substrate in a first direction; a gate structure extending on the active pattern in a second direction, the gate structure intersecting the first direction, the gate structure including a gate electrode; a source/drain pattern on at least one side of the gate structure; a source/drain contact including a lower contact and an upper contact protruding from a region of the lower contact on the source/drain pattern; a gate contact on a region of the gate electrode; an insulating molding layer covering the source/drain contact, the gate structure, and the gate contact; and an interconnection line on the insulating molding layer, the interconnection line having a first via connected to the upper contact of the source/drain contact and a second via connected to the gate contact.

### CROSS-REFERENCE TO RELATED APPLICATION

This application claims the benefit under 35 USC 119 (a) of Korean Patent Application No. 10-2025-0027628 filed on Mar. 4, 2025 in the Korean Intellectual Property Office, the entire disclosure of which is incorporated herein by reference for all purposes.

### BACKGROUND

The present inventive concepts relate to semiconductor devices.

In various semiconductor devices such as logic circuits and memories, a vertical interconnection structure may be used between various conductive elements located on different levels, such as a conductive line in a back end of line (BEOL) or a contact plug connected to an active region such as a source and a drain.

Recently, as semiconductor devices trend towards being more highly integrated, a line width and/or pitch may be reduced or a path may become more complex, which may result in unwanted short circuits of adjacent components due to the interconnection structure, or contact resistance may increase due to an insufficient interconnection area (or contact area).

### SUMMARY

Some example embodiments provide semiconductor devices having a metal interconnection with excellent reliability.

According to some example embodiments, provided is a semiconductor device, the semiconductor device including an active pattern extending on a substrate in a first direction; a gate structure extending on the active pattern in a second direction, the gate structure intersecting the first direction, the gate structure including a gate electrode; a source/drain pattern on at least one side of the gate structure; a source/drain contact including a lower contact and an upper contact protruding from a region of the lower contact, on the source/drain pattern; a gate contact on a region of the gate electrode; an insulating molding layer covering the source/drain contact, the gate structure, and the gate contact; and an interconnection line on the insulating molding layer, the interconnection line having a first via connected to the upper contact of the source/drain contact and a second via connected to the gate contact.

According to some example embodiments, provided is a semiconductor device, the semiconductor device including an active pattern extending on a substrate in a first direction; a gate structure extending on the active pattern in a second direction, the gate structure intersecting the first direction, and including a gate electrode and gate spacers on both sides of the gate electrode; a source/drain pattern on at least one side of the gate structure; a source/drain contact including a lower contact and an upper contact protruding from a first region of the lower contact, on the source/drain pattern; a gate contact having an upper surface on a same level as an upper surface of the upper contact, on a first region of the gate electrode; an insulating molding layer covering the source/drain contact, the gate structure, and the gate contact; and an interconnection line on the insulating molding layer, the interconnection line having a first via connected to the upper contact of the source/drain contact and a second via connected to the gate contact, portions of the gate spacers, between a second region of the gate electrode and a second region of the lower contact, having upper ends lower than an upper surface of the lower contact.

According to some example embodiments, provided is a semiconductor device, the semiconductor device including a first active pattern and a second active pattern, extending in a first direction, respectively and spaced apart from each other in a second direction, intersecting the first direction, on a substrate; a gate structure extending on the first and second active patterns in the second direction, the gate structure including a gate electrode; source/drain patterns on the first and second active patterns on both sides of the gate structure; source/drain contacts respectively on the source/drain patterns, and each of the source/drain contacts including a lower contact having an upper surface at a first level and an upper contact protruding from a region of the lower contact, the upper contact having an upper surface at a second level, the second level higher than the first level; a gate contact having an upper surface at the second level, on a region of the gate electrode; an insulating molding layer covering the source/drain contacts, the gate structure, and the gate contact; and an interconnection line on the insulating molding layer, the interconnection line having first vias respectively connected to the source/drain contacts and a second via connected to the gate contact.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view illustrating a semiconductor device according to some example embodiments of the present inventive concepts;

FIGS. 2A and 2B are cross-sectional side views of the semiconductor device of FIG. 1 taken along lines I1-I1′ and I2-I2′, respectively;

FIGS. 3A and 3B are cross-sectional side views of the semiconductor device of FIG. 1 taken along lines II1-II1′ and II2-II2′;

FIGS. 4A and 4B are cross-sectional side views of a semiconductor device according to some example embodiments of the present inventive concepts, respectively;

FIGS. 5A and 5B are cross-sectional side views of a semiconductor device according to some example embodiments of the present inventive concepts, respectively;

FIG. 6 is a plan view illustrating a semiconductor device according to some example embodiments of the present inventive concepts;

FIGS. 7A and 7B are cross-sectional side views of the semiconductor device of FIG. 6 taken along lines I1-I1′ and I2-I2′, respectively;

FIGS. 8A and 8B are cross-sectional side views of the semiconductor device of FIG. 6 taken along lines II1-II1′ and II2-II2′;

FIGS. 9A to 9F are cross-sectional side views for each process for illustrating a method for manufacturing a semiconductor device according to some example embodiments of the present inventive concepts;

FIGS. 10A to 10E are cross-sectional side views of the semiconductor devices of FIGS. 9A, 9C, 9D, 9E, and 9F, taken along line II1-II1′, respectively; and

FIGS. 11A to 11F are cross-sectional side views of the semiconductor devices of FIGS. 9A, 9B, 9C, 9D, 9E, and 9F, taken along line II2-II2′, respectively.

### DETAILED DESCRIPTION

Hereinafter, various example embodiments of the present inventive concepts will be described in detail with reference to the attached drawings.

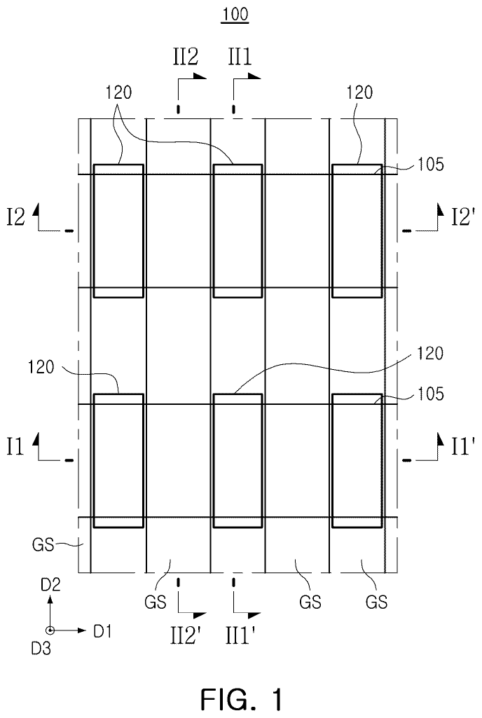

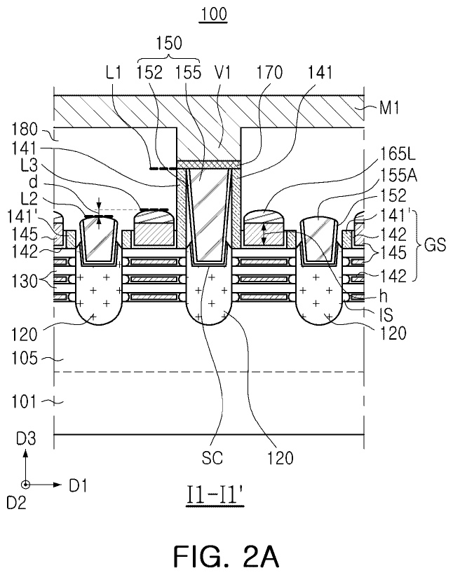

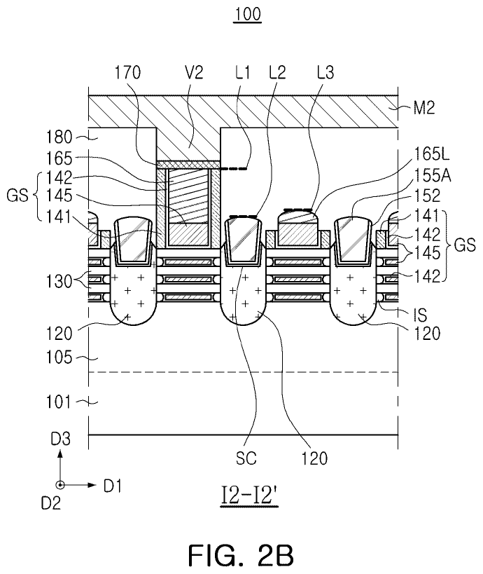

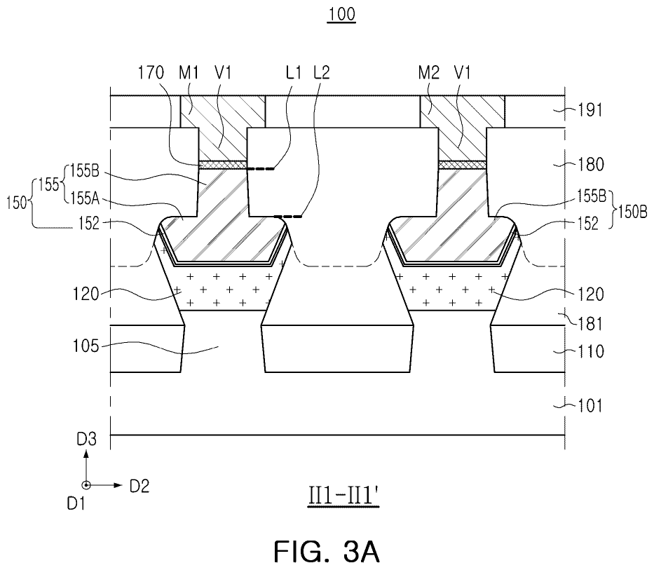

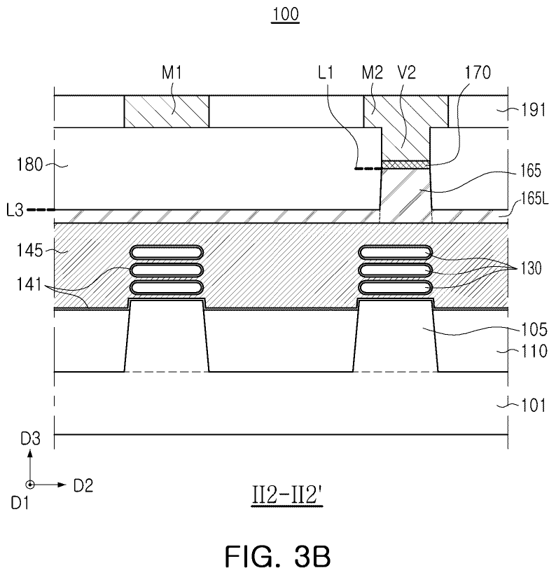

FIG. 1 is a plan view illustrating a semiconductor device according to some example embodiments of the present inventive concepts, FIGS. 2A and 2B are cross-sectional side views of the semiconductor device of FIG. 1, taken along lines I1-I1′ and I2-I2′, respectively, and FIGS. 3A and 3B are cross-sectional side views of the semiconductor device of FIG. 1, taken along lines II1-II1′ and II2-II2′. For convenience of explanation, first and second interconnection lines M1 and M2 and first and second vias V1 and V2 are not illustrated in FIG. 1.

Referring to FIGS. 1 and 2, a semiconductor device 100 according to some example embodiments may include a substrate 101 having active patterns 105, a plurality of channel patterns 130 stacked on the active patterns 105, gate structures GS intersecting the active patterns 105 and surrounding the plurality of channel patterns 130, and source/drain patterns 120 disposed on the active patterns 105 on both sides of the gate structures GS. In some example embodiments, the source/drain patterns 120 may be respectively connected to both sides of the channel patterns 130.

The substrate 101 may include, for example, a semiconductor such as Si and/or Ge, and/or a compound semiconductor such as SiGe, SiC, GaAs, InAs, and/or InP. In some example embodiments, the substrate 101 may have a silicon on insulator (SOI) structure. The substrate 101 may include an active region. The active region may be a conductive region, such as a doped well or a doped structure. For example, the active region may have an n-type well for a PMOS transistor or a p-type well for an NMOS transistor. Each of the active patterns 105 may have a fin shape protruding upwardly (e.g., in a third direction D3 or vertical direction D3) from an upper surface of the active region, and extending in a first direction (e.g., in a first direction D1). The active patterns 105 may be disposed at regular intervals in a second direction (e.g., in a second direction D2), intersecting the first direction D1.

The device isolation layer 110 defines an active region AR. The device isolation layer 110 may include an insulating material of silicon oxide or silicon oxide series. A portion of the active pattern 105 may protrude from an upper surface of the device isolation layer 110. In some example embodiments, the device isolation layer 110 may include a first isolation region defining an active region and a second isolation region defining the active pattern 105. The first isolation region may have a deeper bottom surface than the second isolation region. For example, the first isolation region may be referred to as deep trench isolation (DTI), and the second isolation region may be referred to as shallow trench isolation (STI).

The channel patterns 130 may be stacked on the active pattern 105 in the vertical direction D3. Each of the patterns 130 may include a semiconductor material for providing a channel region. For example, the channel patterns 130 may include at least one of silicon (Si), silicon germanium (SiGe), or germanium (Ge). The channel patterns 130 may be formed of, for example, the same or substantially the same material as the substrate 101. The channel patterns 130 may have a width equal to or smaller than the active pattern 105 in the second direction D2 and may have a width equal to or similar to the gate structure GS in the first direction D1. In some example embodiments, the channel patterns 130 may have a width smaller than a width of the gate structure GS so that side surfaces of the channel patterns 130 is located below the gate structure GS in the first direction D1. Herein, side or side surfaces have a surface facing at least one of the first direction D1 or the second direction D2. In some example embodiments, the channel patterns 130 are illustrated as three, but the number and shape thereof may be variously changed.

The source/drain patterns 120 may be connected to both sides of each of the channel patterns 130. In some example embodiments, the source/drain patterns 120 may be formed by recessing a portion of the active pattern 105 on both sides of each of the gate structures GS and performing selective epitaxial growth (SEG) on the recessed region. The source/drain patterns 120 may include Si, SiGe and/or Ge, and depending on the N-type or P-type transistor, the source/drain patterns 120 may have different materials or different shapes. For example, in the case of a PMOS transistor, the source/drain patterns 120 may include silicon-germanium (SiGe) and may be doped with P-type impurities (e.g., boron (B), indium (In), gallium (Ga)). A cross-section of the source/drain patterns 120 (e.g., FIG. 3A) may be pentagonal. In the case of an NMOS transistor, the source/drain patterns 120 may include silicon and may be doped with N-type impurities (e.g., phosphorus (P), nitrogen (N), arsenic (As), antimony (Sb)). The cross-section of the source/drain patterns 120 may be hexagonal or polygonal with gentle angles (e.g., greater than or equal to about or exactly 90 degrees to less than or equal to about or exactly 180 degrees).

The gate structures GS may extend in a second direction D2 while surrounding a plurality of channel patterns 130, as illustrated in FIG. 1. The gate structures GS may be arranged to be spaced apart at regular intervals in the first direction D1. Specifically, the gate structures GS may be configured to surround the channel patterns 130, respectively. Channel regions of the transistors may be formed in regions of the channel patterns 130 intersecting the gate structures GS. As described above, the semiconductor device 100 according to some example embodiments may be provided as a gate-all-around type field effect transistor.

The gate structures GS may include a gate electrode 145, a gate insulating film 142 between the gate electrode 145 and channel patterns 130, and gate spacers 141 on both side surfaces of the gate electrode 145. The gate electrode 145 may extend in the second direction D2 while surrounding the channel patterns 130, and may have a portion disposed on the uppermost channel pattern 130. The gate electrode 145 may include a conductive material. For example, the gate electrode 145 may include a metal nitride such as titanium nitride (TiN), tantalum nitride (TaN), or tungsten nitride (WN), and/or a metal material such as aluminum (Al), tungsten (W), or molybdenum (Mo), and/or a semiconductor material such as doped polysilicon. In some example embodiments, the gate electrode 145 may be comprised of two or more multilayers.

Gate spacers 141 may be disposed on both side surfaces of the gate electrode 145. The gate spacers 141 may insulate the source/drain patterns 120 and the gate electrode 145. In some example embodiments, the gate spacers 141 may have a multilayer structure. The gate spacers 141 may be formed of oxide, nitride, and oxynitride, and in particular, may be formed of a low-κ film.

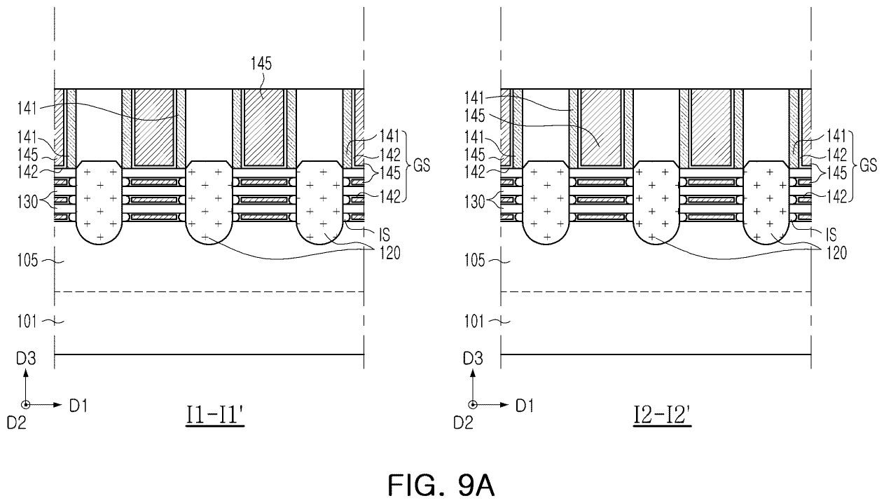

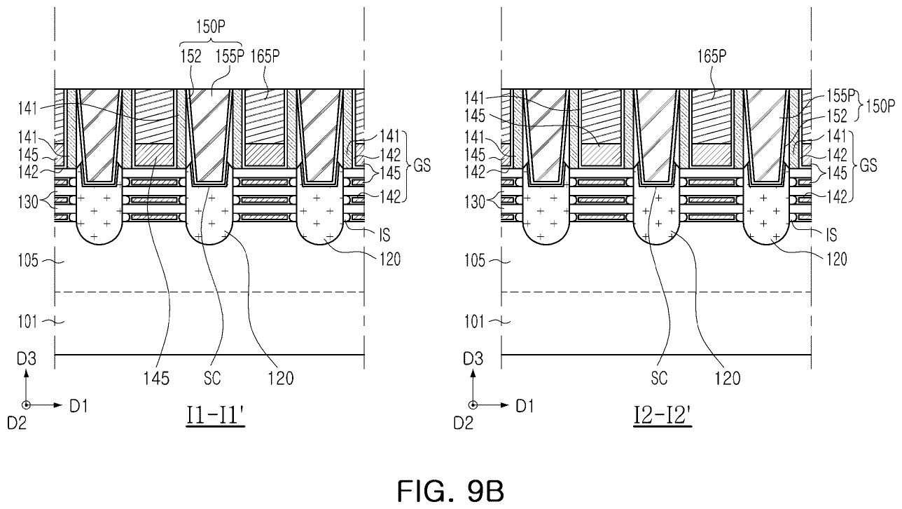

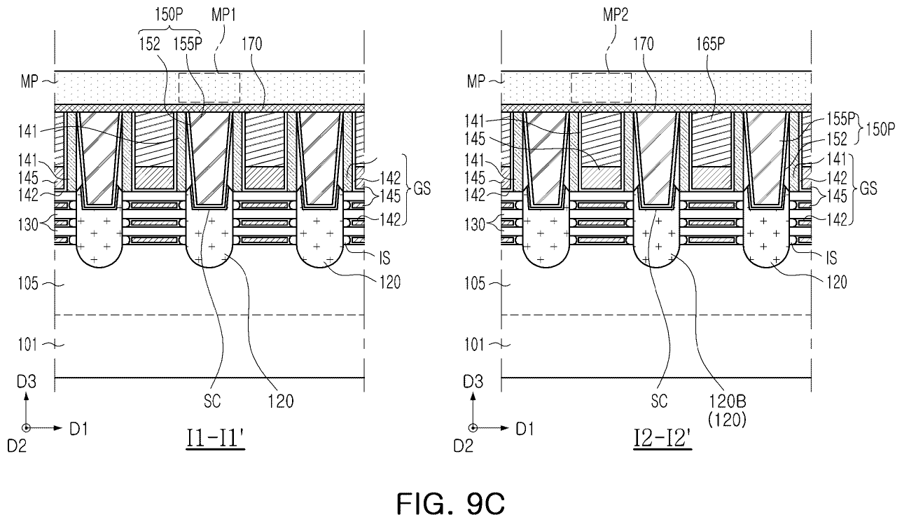

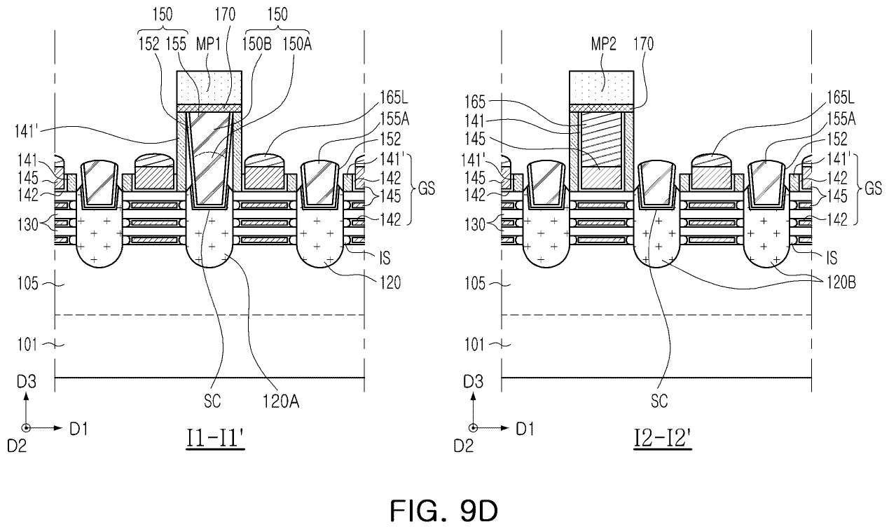

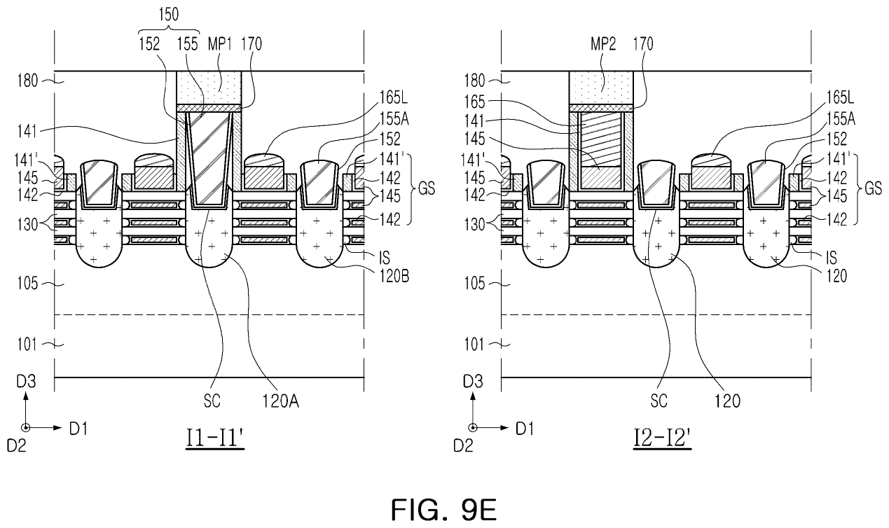

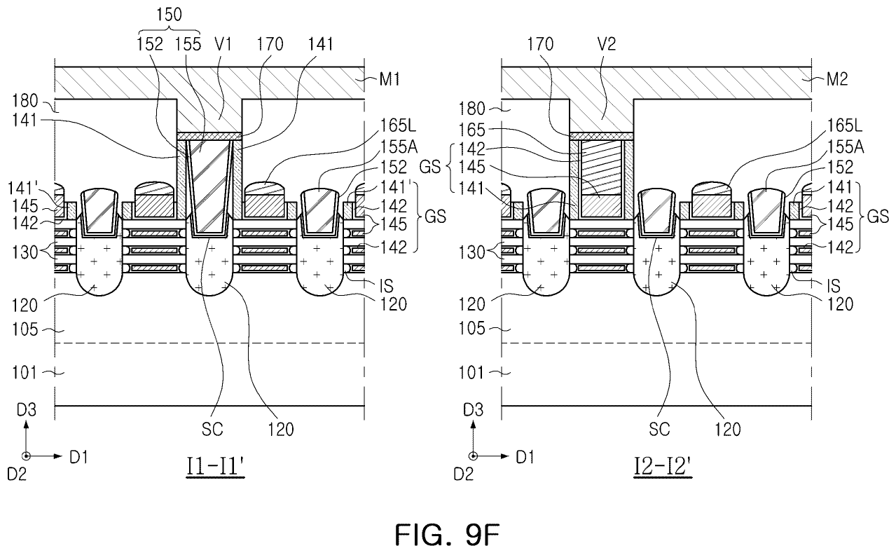

In some example embodiments, an uppermost surface of a gate electrode 145, for example, an upper surface of a gate electrode portion on an uppermost channel pattern, may be relatively low in the third direction D3. The gate electrode portion on the uppermost channel pattern may have a height (h) in the range of greater than or equal to about or exactly 5 nm to less than or equal to about or exactly 20 nm based on the upper surface of the active pattern 105. In some example embodiments, the height (h) of the gate electrode 145 may be in the range of greater than or equal to about or exactly 10 nm to less than or equal to about or exactly 18 nm. After forming the gate electrode 145 between the gate spacers 141, the gate electrode 145 may be recessed using selective etching to have a desired height (h) (see process of FIG. 9B). Referring to FIGS. 2A and 2B, the recessed upper surface of the gate electrode 145 is illustrated as a flat surface, but the gate electrode 145 may have a concave upper surface, but example embodiments thereof are not limited thereto.

In some example embodiments, the gate spacers 141 may have different heights depending on positions thereof. Such a difference in heights may be caused by a recess process defining contact areas (see FIG. 9D), to be described later.

A gate insulating film 142 may be disposed between the active pattern 105 and the gate electrode 145 and between the channel patterns 130 and the gate electrode 145. In some example embodiments, the gate insulating film 142 may be disposed on almost all surfaces except for the uppermost surface of the gate electrode 145. For example, the gate insulating film 142 may extend between the gate electrode 145 and the gate spacers 141. The gate insulating film 142 may include an oxide, a nitride, and/or a high-k material. The high-K material may include a dielectric material having a higher dielectric constant than a silicon oxide film (SiO₂). The high-K material may be at least one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some example embodiments, the gate insulating film 142 may be formed of multilayer films.

Referring to FIGS. 2A and 3A, the semiconductor device 100 may include source/drain contacts 150 respectively connected to the source/drain patterns 120. The source/drain contacts 150 may include a lower contact 150A and an upper contact 150B protruding from a region of the lower contact 150A. The lower contact 150A may extend in a second direction D2, and may have a portion extending into the source/drain pattern 120. The extended portion of the lower contact 150A may overlap at least the uppermost channel pattern 130 in the first direction D1). The upper surface of the upper contact 150B may be provided as a contact region respectively connected to the first vias V1 of the first and second interconnection lines M1 and M2.

Each of the source/drain contacts 150 may include a contact plug 155 and a conductive barrier 152. The conductive barrier 152 may be disposed on a lower surface and some side surfaces of the contact plug 155. The upper contact 150B is a structure integrated with the lower contact 150A, and may include the same or substantially the same material (e.g., contact plug 155) as the lower contact 150A. Referring to FIG. 2A, in the source/drain contact 150, the lower contact 150A and the upper contact 150B have continuous side surfaces, but referring to FIG. 2B, a width of the upper contact 150B in a second direction D2 may be larger than a width of the lower contact 150A in the second direction D2.

In some example embodiments, a conductive barrier 152 may be disposed on a lower surface and a side surface of the contact plug 155 of the lower contact 150A except for an upper surface thereof. On the other hand, in the upper contact 150B, a conductive barrier 152 may be disposed only on some regions of both side surfaces of the contact plug 155 in the first direction D1 (see FIG. 2A), and may not be disposed on both side surfaces of the contact plug 155 in the second direction D2 (see FIG. 2A).

A metal semiconductor compound layer SC may be disposed between the conductive barrier 152 and the source/drain patterns 120. For example, the metal semiconductor compound layer SC may include CoSi, NiSi, and/or TiSi. The conductive barrier 152 may include Ta, TaN, Mn, MnN, WN, Ti, and/or TiN. The contact plug 155 may include tungsten (W), cobalt (Co), titanium (Ti), alloys thereof, or combinations thereof.

Referring to FIGS. 2B and 3B, the semiconductor device 100 according to some example embodiments may include a gate contact 165 connected to a gate electrode 145. The gate contact 165 may be disposed in a region of the gate electrode 145 extending in the second direction. An upper surface of the gate contact 165 may be provided as a contact region connected to each of the second vias V2 of the second interconnection line M2. In some example embodiments, the gate contact 165 may include a metal capping layer 165L covering the upper surface of the gate electrode 145. The metal capping layer 165L is a structure integrated with the gate contact 165, and may include the same or substantially the same material as the gate contact 165. In some example embodiments, the metal capping layer 165L may prevent or reduce contact between the gate electrode 145 and the insulating molding layer 180. Accordingly, the deterioration of electrical reliability due to oxidation of the gate electrode 145, or the like, may be prevented or reduced by exposure (e.g., contact with oxygen) during the recess process and/or contact with the insulating molding layer 180.

In some example embodiments, the upper surface of the source/drain contact 150, for example, the upper surface of the upper contact 150B may have an area and a shape the same as or corresponding to a lower surface of the first via V1 connecting the first and second interconnection lines M1 and M2. Similarly, the upper surface of the gate contact 165 may have an area and a shape the same as or corresponding to a lower surface of the second via V2 connecting the second interconnection line M2.

Referring to FIGS. 2A and 2B, the upper surface of the upper contact 150B and the upper surface of the gate contact 165 may be located on the same level L1. The source/drain contact 150 and the gate contact 165 may be contacted with the first and second vias V1 and V2 at the same level L1. In some example embodiments, conductive barrier layers 170 may be disposed between the first via V1 and the source/drain contact 150 and between the second via V2 and the gate contact 165, respectively. The conductive barrier layers 170 may have the same or substantially the same thickness on the same level. For example, the conductive barrier layers 170 may include Ta, TaN, Mn, MnN, WN, Ti, and/or TiN. In some example embodiments, the conductive barrier layers 170 may be removed, and the source/drain contacts 150 and the gate contacts 165 may be in direct contact with the first and second vias V1 and V2.

In some example embodiments, a metal capping layer 165L and a lower contact 150A may be obtained by the same etching or recessing process (see FIG. 9D). A level L2 of an upper surface of the lower contact 150A may be the same or substantially the same as a level L3 of an upper surface of the metal capping layer 165L, or even if a difference in the levels (d) occurs due to a difference in etching rates depending on the material, since the same etching process is applied, it may be about or exactly 5 nm or less, for example, to about or exactly 0.1 nm (e.g., less than or equal to 5 nm to greater than or equal to 0.1 nm.

In some example embodiments, the source/drain contact 150 may include a metal as different from a metal of the gate contact 165. For example, the contact plug 155 of the source/drain contact 150 may include molybdenum (Mo), and the gate contact 165 may include tungsten (W).

In some example embodiments, gate spacer portions 141′ adjacent to a region of the gate electrode 145 in which the gate contact 165 is not located may have upper ends lower than the upper surface of the gate electrode 145. Similarly thereto, gate spacer portions 141′ adjacent to a region of the lower contact 150A in which the upper contact 150B is not located may have upper ends lower than the level L2 of the upper surface of the lower contact 150A.

Since a recess process for forming the gate contact 165 and the upper contact 150B is performed by a non-selective etching process, the exposed gate spacer portion 141′ may also be etched together with the contact material (see FIG. 9D). During the recess process, the gate spacer portions 141′ may also be etched together to expose edges and side surfaces of the metal capping layer 165L and the lower contact 150A. The metal capping layer 165L and the lower contact 150A may have a rounded edge. Referring to FIGS. 2A and 2B, the metal capping layer 165L and the lower contact 150A may have a convex upper surface.

On the other hand, a gate spacer 141 around the upper contact 150B of the source/drain contact 150 may have an upper end level that is the same or almost the same as the level L1 of the upper surface of the upper contact 150B, and similarly thereto, a gate spacer 141 around the gate contact may have an upper end level that is the same or almost the same as the level L1 of the upper surface of the gate contact.

In the semiconductor device 100 according to some example embodiments, an insulating molding layer 180 covering the source/drain contact 150, the gate structure GS, and the gate contact 165 may be disposed on a device isolation layer 110. For example, the insulating molding layer 180 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. The insulating molding layer 180 may be formed using a chemical vapor deposition (CVD), a flowable-CVD process, and/or a spin coating process.

Referring to FIG. 3A, an interlayer insulating layer 181 remaining after a recess process of FIG. 9D may be located below the insulating molding layer 180. The interlayer insulating layer 181 and the insulating molding layer 180 may include the same or substantially the same material.

The first and second vias may be located in the insulating molding layer 180, while the first and second interconnection lines M1 and M2 may be located in an interconnection insulating layer 191 on the insulating molding layer 180. For example, the interconnection insulating layer 191 may include at least one of silicon oxide, silicon nitride, silicon oxynitride, silicon oxycarbide, silicon oxycarbonitride, silicon carbon nitride, or a low-K material. Although not illustrated, an etch stop layer (not shown) may be disposed between the insulating molding layer and the interconnection insulating layer. For example, the etch stop layer may include aluminum nitride (AlN), aluminum oxynitride (AION), aluminum oxide (AlO), and/or aluminum oxycarbide (AlOC).

According to some example embodiments, the recess process defining the contact regions of the gate and the source/drain may be performed by non-selective etching to remove the gate spacer together with the contact materials (metal materials). By retaining a metal capping layer 165L having the same or substantially the same material as the gate contact 165 on the gate electrode 145, exposure of the gate electrode 145 may be prevented or reduced during the recess process.

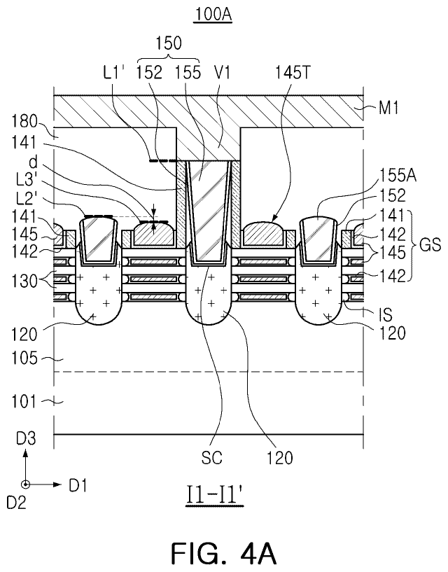

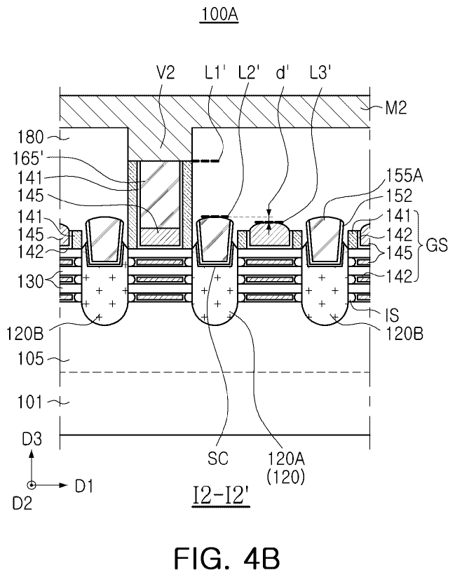

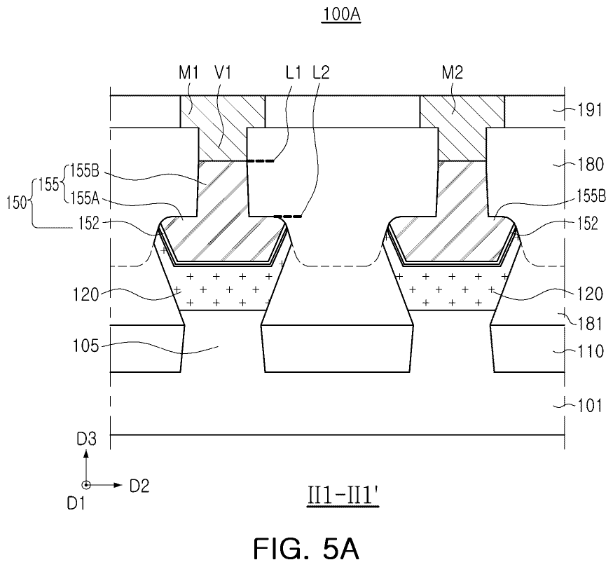

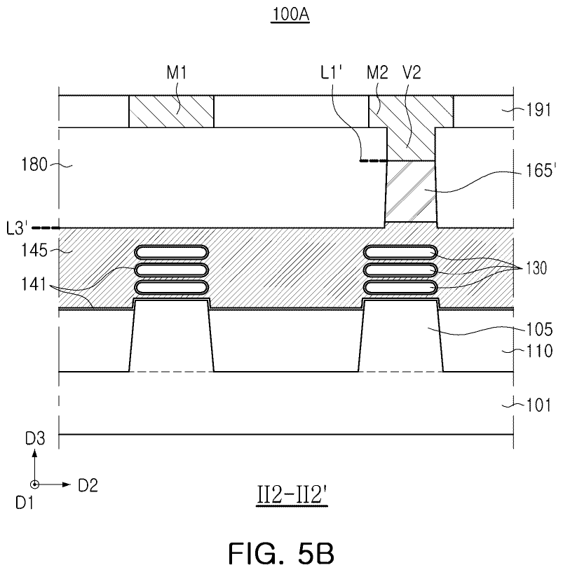

FIGS. 4A and 4B are cross-sectional side views of a semiconductor device according to some example embodiments of the present inventive concepts, respectively, and FIGS. 5A and 5B are cross-sectional side views of a semiconductor device according to some example embodiments of the present inventive concepts, respectively.

FIGS. 4A and 4B are cross-sectional side views of a semiconductor device according to some example embodiments of the present inventive concepts, respectively, and FIGS. 5A and 5B are cross-sectional side views of a semiconductor device according to some example embodiments of the present inventive concepts, respectively. In addition, the components of some example embodiments may be understood by referring to the description of the same or similar components of the semiconductor device 100 illustrated in FIGS. 1 to 3B, unless otherwise specifically stated.

In some example embodiments, in the process of forming the gate contact 165, all gate contact material on other regions (e.g., non-contact regions) of the gate electrode 145 may be removed. In this case, the metal capping layer 165L of the previous example may not remain, and the gate electrode may be exposed. In this case, the exposed gate electrode 145 may have a rounded edge. Referring to FIGS. 4A and 4B, the gate electrode 145 may have a convex upper surface 145T.

Similarly to some example embodiments, the upper surface of the upper contact 150B and the upper surface of the gate contact 165 may be located on the same level L1′. The source/drain contact 150 and the gate contact 165 may be directly contacted with the first and second vias V1 and V2 at the same level L1′. In the process of forming an interconnection line, after removing the conductive barrier layer or the insulating liner layer located on the source/drain contact 150 and the gate contact 165, first and second interconnection lines M1 and M2 may be formed together with the first and second vias V1 and V2.

In some example embodiments, a level L2′ of the upper surface of the lower contact 150A may be higher than a level L3′ of the upper surface of the metal capping layer 165L. In some example embodiments, as well, even if a difference in the levels (d′) occurs due to a difference in the etching rates depending on the material, since the same etching process is applied, it may be about or exactly 5 nm or less, for example, to about or exactly 0.1 nm (e.g., less than or equal to 5 nm to greater than or equal to 0.1 nm). In some example embodiments, the source/drain contact 150 may include the same or substantially the same metal as the metal of the gate contact 165. For example, the contact plug 155 and the gate contact 165 of the source/drain contact 150 may include at least one of aluminum (Al), tungsten (W), cobalt (Co), copper (Cu), ruthenium (Ru), silver (Ag), gold (Au), manganese (Mn), or molybdenum (Mo).

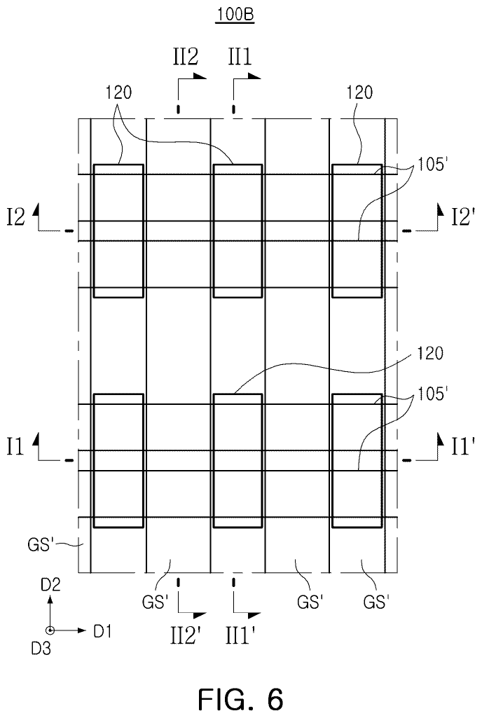

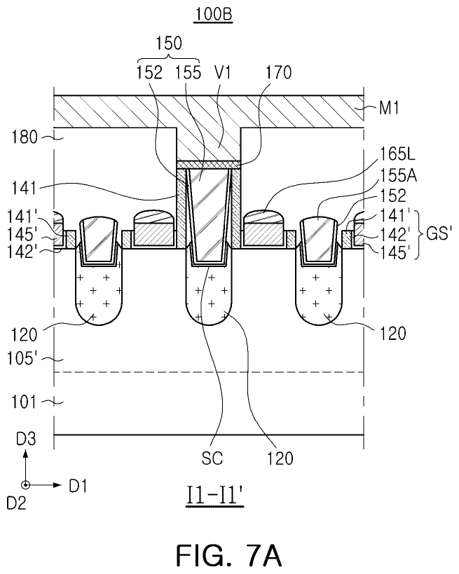

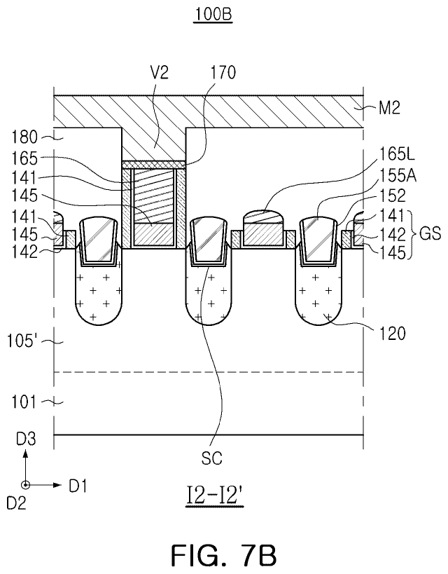

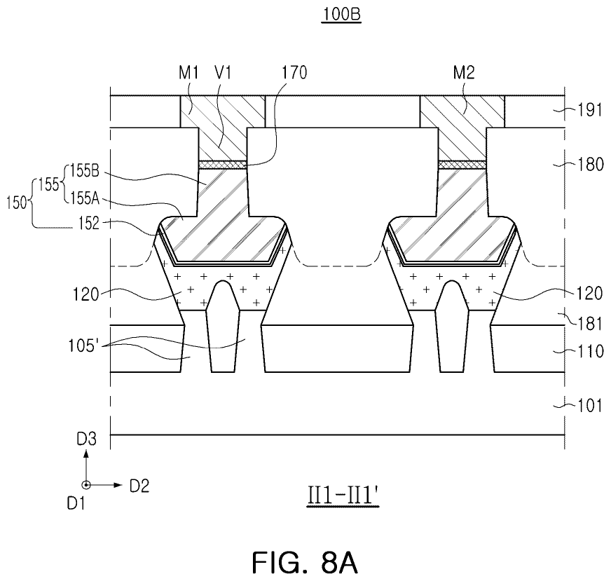

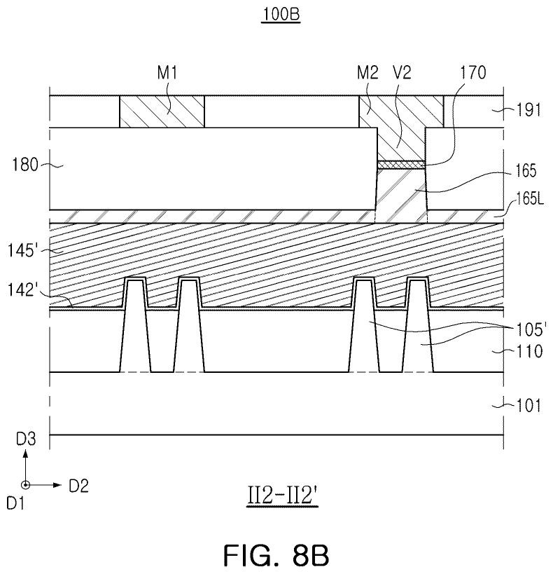

FIG. 6 is a plan view illustrating a semiconductor device according to some example embodiments of the present inventive concepts, FIGS. 7A and 7B are side cross-sectional views of the semiconductor device of FIG. 6, taken along lines I1-I1′ and I2-I2′, respectively, and FIGS. 8A and 8B are side cross-sectional views of the semiconductor device of FIG. 6, taken along lines II1-II1′ and II2-II2′.

Referring to FIGS. 6, 7A and 7B and 8A and 8B, it may be understood that a semiconductor device 100B according to some example embodiments is similar to the semiconductor device 100 illustrated in FIGS. 1 to 3B, except that each of channel regions is provided with two active fins 105′, and the configuration of the gate structure GS is changed accordingly. In addition, the components of some example embodiments may be understood by referring to the description of the same or similar components of the semiconductor device 100 illustrated in FIGS. 1 to 3B, unless otherwise specifically stated.

Each of the channel regions employed in some example embodiments may, unlike some example embodiments, include two active fins 105′. Each of the active fins 105′ may have a structure protruding upwardly, in the vertical direction D3 from an upper surface of the substrate 101, and may extend in a first direction D1. As illustrated in FIG. 8B, the active fins 105′ may be arranged to be in parallel in the second direction D2 on the substrate 101. In some example embodiments, three active fins 105′, adjacently arranged, may provide a channel region for one transistor. In some example embodiments, it is exemplified that the active fins 105′ are provided as two, but example embodiments thereof are not limited thereto, and may be provided as a single or other multiple (e.g., three) amount thereof.

The semiconductor device 100B according to some example embodiments may include source/drain patterns 120 respectively connected to both sides of two active fins 105′.

A gate structure GS' may extend on a device isolation layer 110 in a second direction to intersect the active fins 105′. A gate insulating film 142′ may be formed along an upper surface of the device isolation layer 110 and surfaces of the active fins 105′ protruding from the device isolation layer 110.

Similar to some example embodiments, the source/drain contact 150 employed in some example embodiments may include a lower contact 150A on the source/drain pattern 120 and an upper contact 150B protruding from a region of the lower contact 150A. In addition, a gate contact 165 may be disposed on a region of the gate electrode 145, and may have an upper surface on the same level L1 as an upper surface of the upper contact 150B. In addition, the gate contact 165 may include a metal capping layer 165L extended to cover an upper surface of the other region of the gate electrode 145.

The first and second interconnection lines M1 and M2 may have first vias V1 connected to the upper contact 150B of the source/drain contact 150, and a second via V2 connected to the gate contact 165. The first and second interconnection lines M1 and M2 may be located within an interconnection insulating layer 191 on the insulating molding layer 180, while the first and second vias V1 and V2 may be located within the insulating molding layer 180.

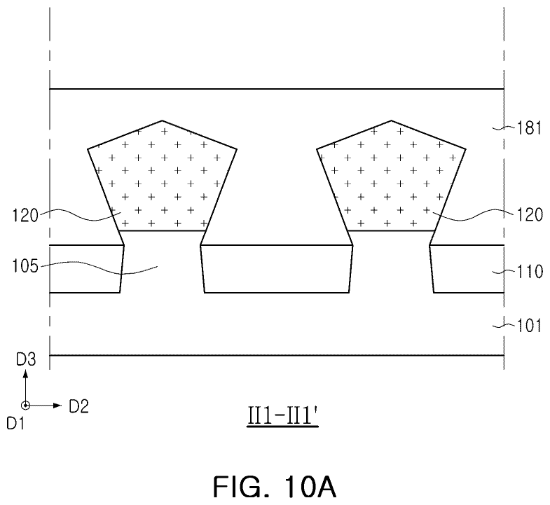

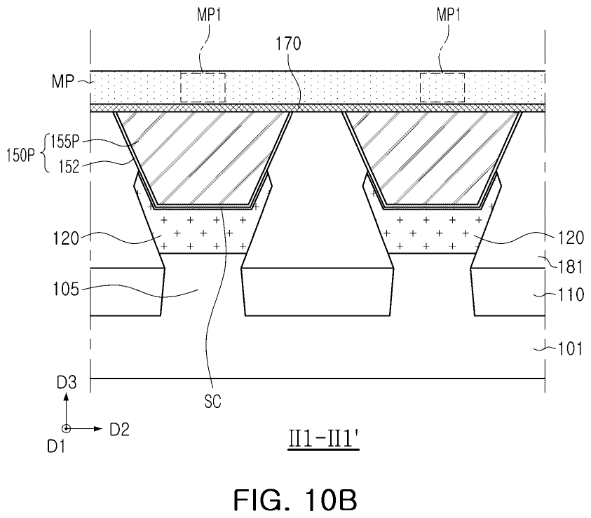

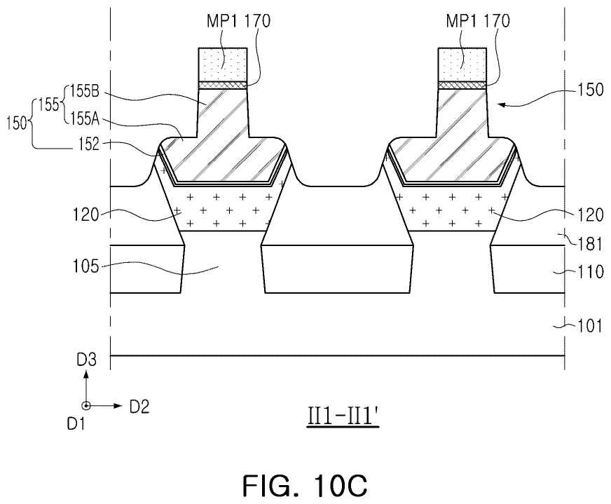

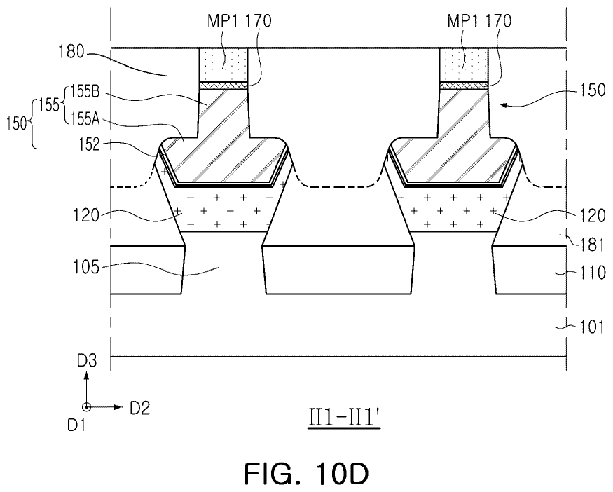

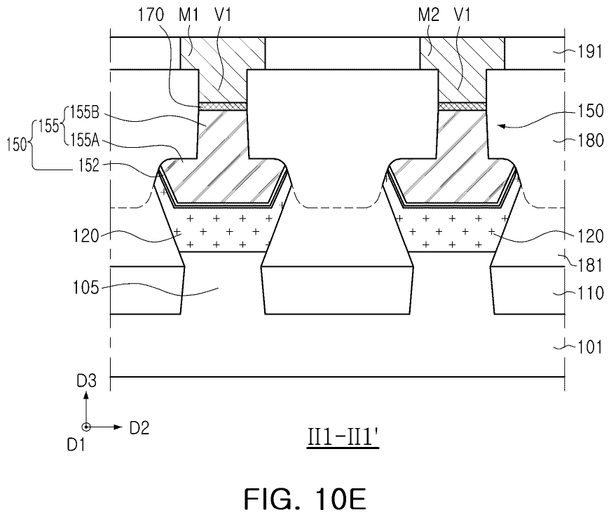

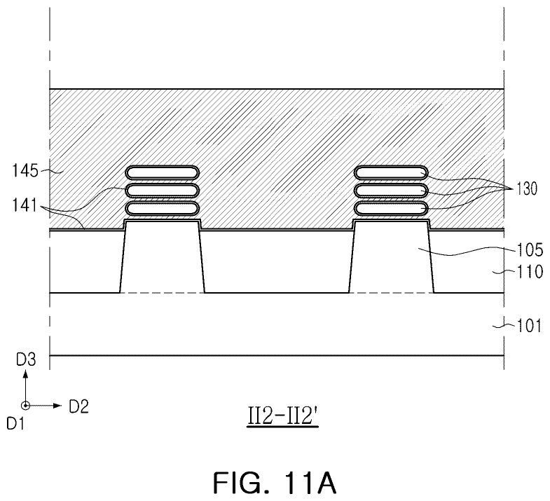

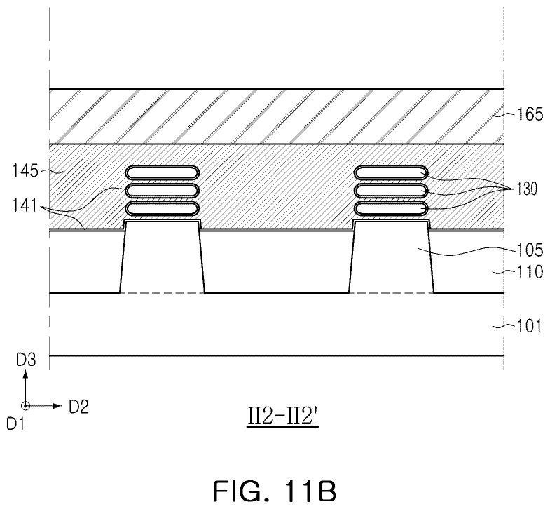

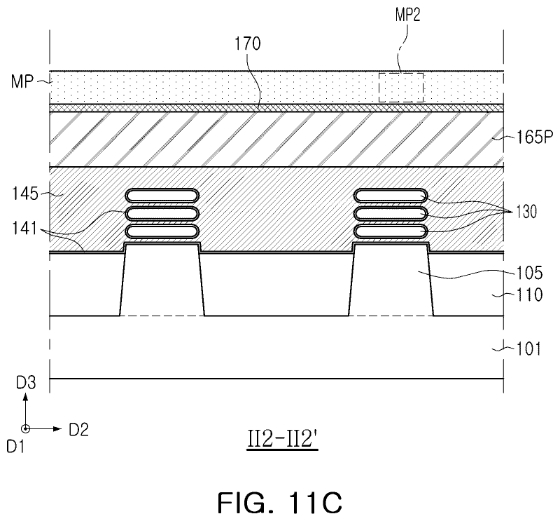

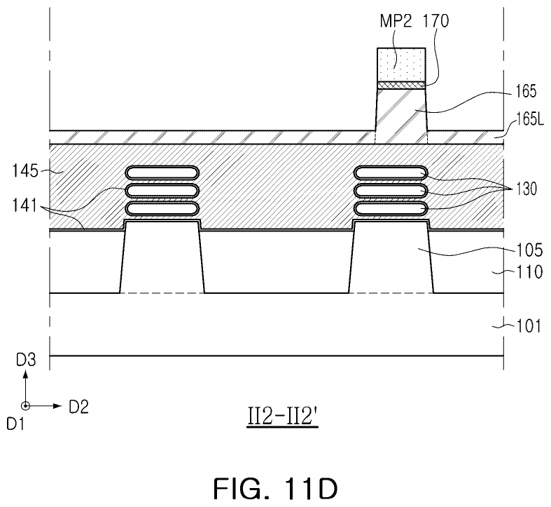

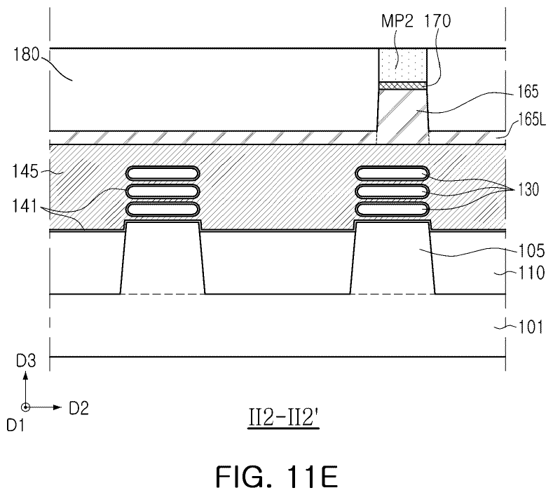

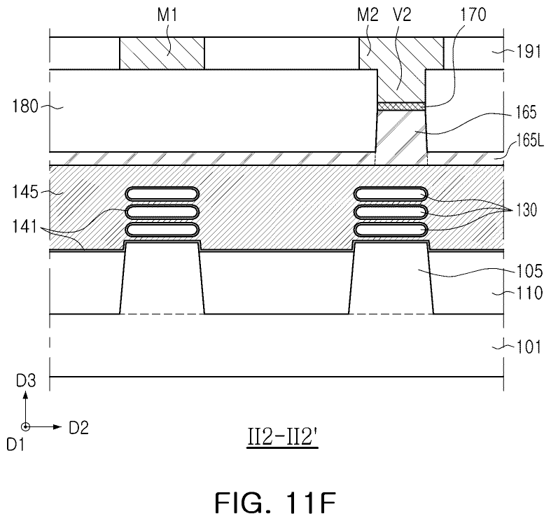

FIGS. 9A to 9F are cross-sectional side views for each process for illustrating a method for manufacturing a semiconductor device according to some example embodiments of the present inventive concepts, FIGS. 10A to 10E are cross-sectional side views of the semiconductor devices of FIGS. 9A, 9C, 9D, 9E, and 9F, taken along line II1-II1′, respectively, and FIGS. 11A to 11F are cross-sectional side views of the semiconductor devices of FIGS. 9A, 9B, 9C, 9D, 9E, and 9F, taken along line II2-II2′, respectively. The manufacturing method according to some example embodiments may be understood as a method for manufacturing the semiconductor device illustrated in FIGS. 1, 2A, 2B, 3A, and 3B.

Referring to FIGS. 9A, 10A, and 11A, a plurality of channel patterns 130 are disposed on an active pattern 105 extending in a first direction D1, and a plurality of gate structures GS extend in a second direction D2 to surround the plurality of channel patterns 130 across the active pattern 105. A source/drain pattern 120 is disposed on both sides of the plurality of gate structures GS to be connected to both sides of the plurality of channel patterns 130.

The semiconductor structures illustrated in FIGS. 9A, 10A, and 11A can be obtained through the processes which follow. After recessing the regions of the active pattern 105 between dummy gate structures (not shown), an epitaxial layer may be re-grown in the recessed region to form source/drain patterns 120, and an interlayer insulating layer 181 may be formed to cover the source/drain patterns 120 between the dummy gate structures. Next, sacrificial material layers (not shown) between the gate spacers 141 and between the channel patterns 130 in the dummy gate structure may be removed from the dummy gate structure, and a gate insulating film 142 may be conformally formed in the removed spaces, and then a gate electrode 145 may be filled. The gate electrode 145 may be disposed on the gate insulating film 142 between the gate spacers 141.

The gate electrodes 145 may include a conductive material. For example, the gate electrodes 145 may include a metal nitride, such as a titanium nitride (TiN), a tantalum nitride (TaN), and/or a tungsten nitride (WN), and/or a metal material, such as aluminum (Al), tungsten (W), or molybdenum (Mo), and/or a semiconductor material, such as doped polysilicon. In some example embodiments, the gate electrodes 145 may be comprised of two or more multilayers.

Next, referring to FIG. 9B and FIG. 11B, after recessing the gate electrodes 145, free gate contacts 165P may be formed in the recessed space, and free source/drain contacts 150P connected to the source/drain patterns 120 in the active pattern 105 may be formed.

First, the gate electrodes 145 may be recessed using selective etching to have a desired height. The gate electrodes 145 may be etched with high selectivity for dielectric materials such as gate spacers 141. A target height of the recessed gate electrodes may be in the range of greater than or equal to about or exactly 5 nm to less than or equal to about or exactly 20 nm based on an upper surface of the active pattern 105. A recessed upper surface of the gate electrode 145 may be illustrated as a flat surface, but the gate electrodes 145 may have a concave upper surface, but example embodiments thereof are not limited. A free gate contact 165P may be filled on the recessed space, that is, on the gate electrodes 145 between the gate spacers 141. The present filling process may be performed by a process of performing a deposition process of the free gate contact 165P so that the recessed space is filled, and then a polishing process so that a portion of the free gate contact 165P on an interlayer insulating layer 181 is removed.

A contact hole (not shown) connected to the source/drain patterns 120 may be formed on the interlayer insulating layer 181. The contact hole may include a region in which a portion of the source/drain patterns are reset. Next, free source/drain contacts 150P may be formed by conformally forming a conductive barrier 152 in the contact hole and then filling the contact plug 155P. The conductive barrier 152 may be disposed on a lower surface and a side surface of the contact plug 155. Additionally, a metal semiconductor compound layer SC may be formed between the conductive barrier 152 and the source/drain patterns 120. For example, the metal semiconductor compound layer (SC) may include CoSi, NiSi, and/or TiSi.

For example, the conductive barrier 152 may include Ta, TaN, Mn, MnN, WN, Ti, and/or TiN. For example, the free gate contact 165P and the free contact plug 155P may include tungsten (W), cobalt (Co), titanium (Ti), alloys thereof, or combinations thereof. In some example embodiments, the contact plug 155P of the free source/drain contacts 150P may include a metal different from the metal of the free gate contact 165P. For example, the contact plug 155P may include molybdenum (Mo), and the free gate contact 165P may include tungsten (W).

Next, referring to FIG. 9C, FIG. 10B, and FIG. 11C, a conductive barrier layer 170 and a mask layer MP may be sequentially formed on the interlayer insulating layer 181 and the gate structure GS.

After forming the conductive barrier layer 170, a mask layer MP may be formed. For example, the conductive barrier layers 170 may include Ta, TaN, Mn, MnN, WN, Ti, and/or TiN. In some example embodiments, the conductive barrier layer 170 may be employed, but in some example embodiments, an insulating liner layer may be introduced.

Next, using a photolithography process, other regions except for mask patterns MP1 and MP2 corresponding to via contact regions may be removed from the mask layer MP. The mask patterns may define contact regions to be connected to interconnection lines (“M1” and “M2” in FIG. 9F) in the free source/drain contact 150P and the free gate contact 165P. The mask patterns may include first mask patterns MP1 for source/drain contacts and second mask patterns MP2 for gate contacts. The first mask patterns MP1 may define an actual contact region of each of the preliminary source/drain contacts 150P, and the second mask patterns MP2 may define an actual contact region of each of the preliminary gate contacts 165P.

In some example embodiments, widths of the first mask patterns MP1 and the second mask patterns MP2 in the first direction D1 may be defined to cover at least a portion of the gate spacers 141 around the regions for contact.

Next, referring to FIGS. 9D, 10C, and 11D, the exposed region may be recessed using the first mask patterns MP1 and the second mask pattern MP2.

In some example embodiments, the recess process may be performed by non-selective etching. Specifically, not only metals such as the free gate contact 165P and the free source/drain contact 150P, but also dielectric materials such as the interlayer insulating layer 181, the gate insulating film 142, and the gate spacer 141 may be etched.

After the etching process, referring to FIG. 11C together with FIG. 9D, a lower contact 150A may be provided by retaining a free source/drain contact 150P of some thickness in a non-contact region. A contact region of the free source/drain contact 150P defined by the first mask pattern MP1 may provide an upper contact 150B. A final source/drain contact 150 may include a lower contact 150A and an upper contact 150B protruding from the contact region of the lower contact 150A.

After the etching process, referring to FIG. 11D together with FIG. 9D, a metal capping layer 165L on the gate electrode 145 may be provided by retaining a free gate contact 165P of some thickness in the non-contact region. A contact region of the free gate contact 165P defined by the second mask pattern MP2 may provide the gate contact 165. A level of an upper surface of the gate contact 165 may be the same or substantially the same as a level of an upper surface of the upper contact 150B.

In addition, a level of an upper surface of the lower contact 150A may be the same or substantially the same as a level L3 of an upper surface of a metal capping layer 165L, or may be about or exactly 5 nm or less, for example, to about or exactly 0.1 nm (e.g., less than or equal to 5 nm to greater than or equal to 0.1 nm) even if a difference in the levels occurs due to a difference in etching rates depending on the material.

Meanwhile, in the non-contact region, dielectric elements such as gate spacers may also be removed. Gate spacer portions 141′ adjacent to a region of the gate electrode 145 in which the gate contact 165 is not located may have upper ends lower than the upper surface of the gate electrode 145. Similarly, gate spacer portions 141′ adjacent to a region of the lower contact 150A in which the upper contact 150B is not located may have upper ends lower than the level of the upper surface of the lower contact 150A.

On the other hand, the gate spacer 141 covered by the first and second mask patterns MP1 and MP2 may remain as is. Specifically, the gate spacer 141 around the upper contact 150B of the source/drain contact 150 may have an upper end level which is the same or almost the same as the level L1 of the upper surface of the upper contact 150B, and similarly thereto, the gate spacer 141 around the gate contact can have an upper end at a level almost the same or the same level as the level L1 of the upper surface of the gate contact.

In addition, during the recess process, since the gate spacer portions 141′ are also etched together to expose edges and side surfaces of the metal capping layer 165L and the lower contact 150A, the metal capping layer 165L and the lower contact 150A may be etched to have rounded edges. For example, as illustrated in FIG. 9D, the metal capping layer 165L and the lower contact 150A may have a convex upper surface.

Next, referring to FIGS. 9E, 10D, and 11E, an insulating molding layer 180 may be formed to fill the recessed regions, and a planarization process may be performed so that the upper surfaces of the first and second mask patterns MP1 and MP2 are exposed.

In some example embodiments, the insulating molding layer 180 may be formed to cover the recessed non-contact region on the remaining interlayer insulating layer 181. In this process, the metal capping layer 165L may reduce or prevent contact between the gate electrode 145 and the insulating molding layer 180. In this manner, it is possible to reduce or prevent a deterioration of electrical reliability due to oxidation of the gate electrode 145 due to exposure (e.g., oxygen contact) during the recess process and/or contact with the insulating molding layer 180. Therefore, a degree of freedom in selecting a material of the insulating molding layer 180 may be increased.

Next, referring to FIGS. 9F, 10E, and 11F, the first and second interconnection lines M1 and M2 may be formed after the first and second mask patterns MP1 and MP2 are removed.

In some example embodiments, the process may include forming first and second vias V1 and V2 defined in by spaces from which the first and second mask patterns MP1 and MP2 are removed. The first and second vias V1 and V2 may be part of the first and second interconnection lines M1 and M2. The first and second vias V1 and V2 may be located in an insulating molding layer 180, while the first and second interconnection lines M1 and M2 may be located in an interconnection insulation layer 191 on the insulating molding layer 180. That is, while the first and second vias V1 and V2 and the first and second interconnection lines M1 and M2 may be integral, they may be defined by a plane on an uppermost surface of the insulating molding layer 180.

In the process of removing the first and second mask patterns MP1 and MP2, the conductive barrier layers 170 may also be removed. In this case, the source/drain contact 150 and the gate contact 165 may be in direct contact with the first and second vias V1 and V2. In some example embodiments, even when an insulating liner layer is used instead of the conductive barrier layers 170, the insulating liner layer may be removed during the process of removing the first and second mask patterns MP1 and MP2.

As set forth above, according to the example embodiments described above, a high-K structure such as a gate spacer may also be removed with contact materials by performing a non-selective etching process defining contact regions of a gate contact and a source/drain contact. Exposure of a gate electrode during a recess process may be reduced or prevented by retaining a metal capping layer having the same or substantially the same material as the gate contact on the gate electrode.

According to some example embodiments, provided is a method of manufacturing a semiconductor device, the method including forming channel patterns on an active pattern, the channel patterns extending in a first direction, forming gate structures surrounding the channel patterns, the gate structures extending in a second direction, forming source/drain patterns on both sides of each of the gate structures, the source/drain patterns connected to both sides of the channel patterns, recessing the gate electrodes to define recessed spaces, forming free gate contacts in the first recessed spaces, forming free source/drain contacts connected to the source/drain patterns in the active pattern, forming a conductive barrier layer and a mask layer on an interlayer insulating layer and the gate structures, recessing regions defined by the mask layer which form recessed regions and metal capping layers and gate contacts on the gate electrodes, the gate contacts each including an upper contact and a lower contact, and form gate spacer portions adjacent to the gate electrodes having a respective one of the metal capping layers and gate spacers adjacent to the gate electrodes having a respective one of the gate contacts, forming an insulating molding layer on the recessed regions, removing the mask layer, forming a first interconnection line and a second interconnection line, the first interconnection line having first vias connected to the upper contact of the source/drain contacts and the second interconnection line having second vias connected to the gate contacts.

According to some example embodiments, the method further includes the level of an upper surface of the gate contact may be same as a level of an upper surface of the upper contact.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B. While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

The various advantageous and beneficial advantages and effects of the present inventive concepts are not limited to the above-described contents, and will be more easily understood in the course of explaining specific example embodiments of the present inventive concepts.

While example embodiments have been illustrated and described above, it will be apparent to those skilled in the art that modifications and variations could be made without departing from the scope of the present inventive concepts as defined by the appended claims.

What is claimed is:

1. A semiconductor device, comprising:
an active pattern extending on a substrate in a first direction;
a gate structure extending on the active pattern in a second direction, the gate structure intersecting the first direction, the gate structure including a gate electrode;
a source/drain pattern on at least one side of the gate structure;
a source/drain contact including a lower contact on the source/drain pattern and an upper contact protruding from a region of the lower contact;
a gate contact on a first region of the gate electrode;
an insulating molding layer covering the source/drain contact, the gate structure, and the gate contact; and
an interconnection line on the insulating molding layer, the interconnection line having a first via connected to the upper contact of the source/drain contact and a second via connected to the gate contact.

2. The semiconductor device of claim 1, wherein the gate contact includes a metal capping layer covering an upper surface of a second region of the gate electrode.

3. The semiconductor device of claim 2, wherein a difference in levels between an upper surface of the metal capping layer and an upper surface of the lower contact is less than or equal to 5 nm to greater than or equal to 0.1 nm.

4. The semiconductor device of claim 1, wherein
an upper surface of a second region of the gate electrode is in contact with the insulating molding layer, and
a difference in levels between the upper surface of the second region of the gate electrode and an upper surface of the lower contact is less than or equal to 5 nm to greater than or equal to 0.1 nm.

5. The semiconductor device of claim 1, wherein an upper surface of a second region of the gate electrode has a height of greater than or equal to 5 nm to less than or equal to 20 nm based on an upper surface of the active pattern.

6. The semiconductor device of claim 1, wherein the gate structure further includes gate spacers respectively on both side surfaces of the gate electrode.

7. The semiconductor device of claim 6, wherein portions of the gate spacers adjacent to a second region of the gate electrode have upper ends lower than an upper surface of the gate electrode.

8. The semiconductor device of claim 7, wherein the upper surface of the gate electrode has a rounded edge.

9. The semiconductor device of claim 6, wherein portions of the gate spacers adjacent to a second region of the lower contact have upper ends lower than an upper surface of the lower contact.

10. The semiconductor device of claim 9, wherein the upper surface of the lower contact of the source/drain contact has a rounded edge.

11. The semiconductor device of claim 6, wherein portions of the gate spacers adjacent to the upper contact have upper ends at a same level as an upper surface of the upper contact.

12. The semiconductor device of claim 1, wherein the upper contact of the source/drain contact has an upper surface at a same level as the upper surface of the gate contact.

13. The semiconductor device of claim 1, further comprising:
conductive barriers respectively between the first via and the source/drain contact and between the second via and the gate contact.

14. The semiconductor device of claim 1, wherein the source/drain contact includes a metal different from a metal of the gate contact.

15. The semiconductor device of claim 1, wherein the source/drain contact includes molybdenum (Mo), and the gate contact includes tungsten (W).

16. A semiconductor device, comprising:
an active pattern extending on a substrate in a first direction;
a gate structure extending on the active pattern in a second direction, the gate structure intersecting the first direction, the gate structure including a gate electrode and gate spacers on both sides of the gate electrode;
a source/drain pattern on at least one side of the gate structure;
a source/drain contact including a lower contact and an upper contact protruding from a first region of the lower contact, on the source/drain pattern;
a gate contact having an upper surface on a same level as an upper surface of the upper contact, on a first region of the gate electrode;
an insulating molding layer covering the source/drain contact, the gate structure, and the gate contact; and
an interconnection line on the insulating molding layer, the interconnection line having a first via connected to the upper contact of the source/drain contact and a second via connected to the gate contact,
portions of the gate spacers, between a second region of the gate electrode and a second region of the lower contact, having upper ends lower than an upper surface of the lower contact.

17. The semiconductor device of claim 16, wherein the gate contact includes a metal capping layer covering an upper surface of the second region of the gate electrode.

18. The semiconductor device of claim 17, wherein a difference in levels between an upper surface of the metal capping layer and the upper surface of the source/drain contact is less than or equal to 5 nm to greater than or equal to 0.1 nm.

19. The semiconductor device of claim 17, wherein a cross-section of each of the lower contact and the metal capping layer in the first direction has a convex upper surface.

20. A semiconductor device, comprising:
a first active pattern and a second active pattern, extending in a first direction and spaced apart from each other in a second direction, intersecting the first direction, on a substrate;
a gate structure extending on the first and second active patterns in the second direction, and including a gate electrode;
source/drain patterns on the first and second active patterns on both sides of the gate structure;
source/drain contacts respectively on the source/drain patterns, and each of the source/drain contacts including a lower contact having an upper surface at a first level and an upper contact protruding from a region of the lower contact, the upper contact having an upper surface at a second level, the second level higher than the first level;
a gate contact having an upper surface at the second level, on a region of the gate electrode;
an insulating molding layer covering the source/drain contacts, the gate structure, and the gate contact; and
an interconnection line on the insulating molding layer, the interconnection line having first vias respectively connected to the source/drain contacts and a second via connected to the gate contact.
